(19) United States
(12) Patent Application Publication
(10) Pub. No.: US 2014/0201584 A1
(43) Pub. Date: Jul. 17, 2014

(54) SCAN TEST CIRCUITRY COMPRISING AT LEAST ONE SCAN CHAIN AND ASSOCIATED RESET MULTIPLEXING CIRCUITRY

(71) Applicant: LSI CORPORATION, San Jose, CA (US)

(72) Inventors: Ramesh C. Tekumalla, Breinigsville, PA (US); Priyesh Kumar, Pune (IN); Prakash Krishnamoorthy, Allentown, PA (US)

(73) Assignee: LSI Corporation, San Jose, CA (US)

(21) Appl. No.: 13/743,687

(22) Filed: Jan. 17, 2013

(51) Int. Cl. G01R 31/3177

(52) U.S. Cl. CPC G01R 31/3177
USPC 714/727

(57) ABSTRACT

An integrated circuit comprises scan test circuitry and additional circuitry subject to testing utilizing the scan test circuitry. The scan test circuitry comprises at least one scan chain having a plurality of scan cells. The scan test circuitry further comprises control circuitry configured to control selective application of at least a particular one of a plurality of reset signals to reset inputs of at least a subset of the scan cells of the scan chain. For example, the control circuitry may comprise a first reset multiplexer configured to select between a first functional mode reset signal and a first scan mode reset signal for application to reset inputs of respective scan cells of the scan chain, and an additional multiplexer configured to select between an additional functional mode reset signal and an additional scan mode reset signal for application to reset inputs of respective internal flip-flops of the additional circuitry.

### FIELD

The field relates generally to integrated circuits, and more particularly to scan testing of integrated circuits.

### BACKGROUND

Integrated circuits are often designed to incorporate scan test circuitry that facilitates testing for various internal fault conditions. Such scan test circuitry typically comprises scan chains comprising multiple scan cells. The scan cells may be implemented, by way of example, utilizing respective flip-flops. The scan cells of a given scan chain are configurable to form a serial shift register for applying test patterns at inputs to combinational logic of the integrated circuit. The scan cells of the given scan chain are also used to capture outputs from other combinational logic of the integrated circuit.

Scan testing of an integrated circuit may therefore be viewed as being performed in two repeating phases, namely, a scan shift phase in which the flip-flops of the scan chain are configured as a serial shift register for shifting in and shifting out of test patterns, and a scan capture phase in which the flip-flops of the scan chain capture combinational logic outputs. These two repeating scan test phases may be collectively referred to herein as a scan test mode of operation of the integrated circuit, or as simply a scan mode of operation. Outside of the scan test mode and its scan shift and scan capture phases, the integrated circuit may be said to be in a functional mode of operation. Other definitions of the scan test and functional operating modes may also be used.

As integrated circuits have become increasingly complex, scan compression techniques have been developed which reduce the number of test patterns that need to be applied when testing a given integrated circuit, and therefore also reduce the required test time. Additional details regarding compressed scan testing are disclosed in U.S. Pat. No. 7,831,876, entitled “Testing a Circuit with Compressed Scan Subsets,” which is commonly assigned herewith and incorporated by reference herein.

Despite the performance advantages associated with scan compression, there nonetheless remains a need for further improvements in scan test circuitry. For example, conventional scan test circuitry can introduce a significant amount of overhead that unduly increases circuit area while also adversely impacting performance, particularly for high-speed integrated circuit designs. As a result, in certain integrated circuits such as system-on-chip (SOC) integrated circuits, the amount of scan test circuitry may have to be reduced in order to meet strict circuit area and performance requirements. Conventional approaches in the SOC context may even remove scan test circuitry entirely from certain modules, blocks or other types of circuit cores in order to meet the circuit area and performance requirements, leading to an undesirable reduction in fault coverage for the overall design.

### SUMMARY

In one embodiment, an integrated circuit comprises scan test circuitry and additional circuitry subject to testing utilizing the scan test circuitry. The scan test circuitry comprises at least one scan chain having a plurality of scan cells. The scan test circuitry further comprises control circuitry configured to control selective application of at least a particular one of a plurality of reset signals to reset inputs of at least a subset of the scan cells of the scan chain. The control circuitry may illustratively comprise reset multiplexing circuitry that includes a plurality of reset multiplexers.

By way of example only, the control circuitry may comprise a first reset multiplexer configured to select between a first functional mode reset signal and a first scan mode reset signal for application to reset inputs of respective scan cells of the scan chain, and at least one additional reset multiplexer configured to select between an additional functional mode reset signal and an additional scan mode reset signal for application to reset inputs of respective internal flip-flops of the additional circuitry.

The scan cells of the scan chain may comprise, again by way of example only, respective boundary flip-flops of a circuit core of the integrated circuit. In such an arrangement, the internal flip-flops and other logic circuitry of the circuit core can be scan tested without requiring any significant additional scan test circuitry within the circuit core itself. As a result, improved fault coverage is provided for the integrated circuit while the circuit area and performance impacts of the scan testing are minimized.

Other embodiments of the invention include but are not limited to methods, apparatus, systems, processing devices and computer-readable storage media having computer program code embodied therein.

### BRIEF DESCRIPTION OF THE DRAWINGS

FIG. 1 is a block diagram showing an integrated circuit testing system comprising a tester and an integrated circuit under test in one embodiment.

FIG. 2 shows an exemplary circuit core that may be configured with associated control circuitry to support scan testing of internal logic circuitry in an illustrative embodiment.

FIG. 3 shows the circuit core of FIG. 2 and associated control circuitry configured to support scan testing in the FIG. 1 system.

FIG. 4 is a timing diagram illustrating the operation of the control circuitry of FIG. 3.

FIG. 5 shows one possible implementation of the testing system of FIG. 1.

FIG. 6 is a block diagram of a processing system for generating an integrated circuit design comprising control circuitry of the type illustrated in FIG. 3.

### DETAILED DESCRIPTION

Embodiments of the invention will be illustrated herein in conjunction with exemplary testing systems and corresponding integrated circuits comprising scan test circuitry for supporting scan testing of additional circuitry of those integrated circuits. It should be understood, however, that embodiments of the invention are more generally applicable to any testing system or associated integrated circuit in which it is desirable to provide improved scan test coverage for an integrated circuit.

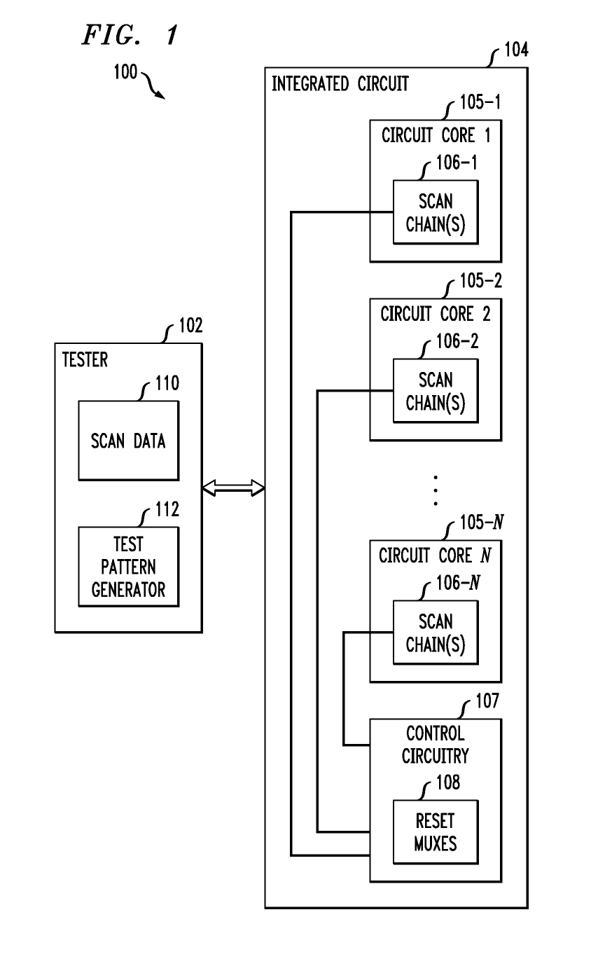

FIG. 1 shows an embodiment of the invention in which a testing system 100 comprises a tester 102 and an integrated circuit under test 104. The integrated circuit 104 comprises a plurality of circuit cores 105-1, 105-2, . . . 105-N, each comprising one or more scan chains 106-1, 106-2, . . . 106-N. The integrated circuit 104 further comprises control circuitry 107 that is coupled to the scan chains 105 and comprises reset multiplexing circuitry in the form of one or more reset multiplexers 108 for each of the circuit cores 105. The circuit cores 105 may represent different circuit cores of an SOC integrated circuit, such as respective read channel and additional cores of an SOC integrated circuit in a hard disk drive (HDD) controller application, designed for reading data from and writing data to one or more magnetic storage disks of an HDD. Numerous other types of integrated circuits and circuit cores may be used in other embodiments.

The scan chains 106 and the control circuitry 107 are an example of what is more generally referred to herein as “scan test circuitry.” Portions of the circuit cores 105 other than the scan chains 106 are examples of what are more generally referred to herein as “additional circuitry” of the integrated circuit 104, that is subject to testing utilizing the scan test circuitry. The scan test circuitry is therefore coupled to additional circuitry that is subject to testing utilizing the scan test circuitry.

As will be described in greater detail below, a given one of the reset multiplexers 108 of the control circuitry 107 is generally configured to control selective application of at least a particular one of a plurality of reset signals to reset inputs of at least a subset of the scan cells of the corresponding scan chain 106.

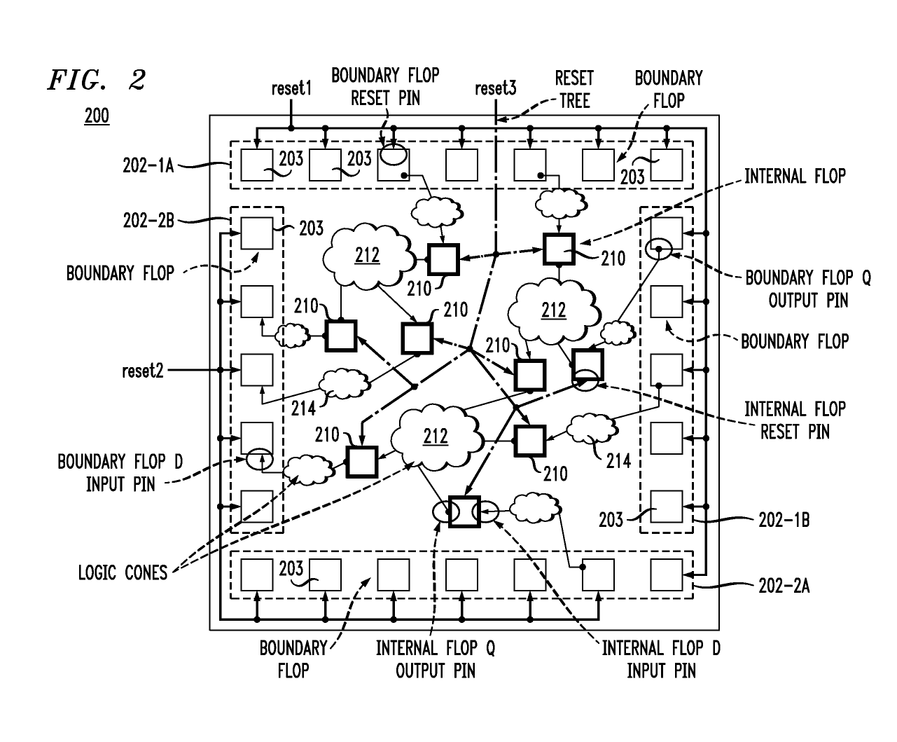

By way of example, in one embodiment to be described below in conjunction with FIGS. 2 through 4, one of the scan chains 106 is formed using boundary flip-flops of the corresponding circuit core 105, and one of the reset multiplexers 108 is configured to select between a functional mode reset signal and a scan mode reset signal for application to the reset inputs of at least a subset of the scan cells of the scan chain responsive to a select signal. More particularly, the scan cells of the scan chain are separated into at least first and second subsets, with a first one of the reset multiplexers 108 configured to select a particular one of a plurality of first reset signals for application to reset inputs of respective scan cells in the first subset of scan cells, and a second one of the reset multiplexers 108 configured to select a particular one of a plurality of second reset signals for application to reset inputs of respective scan cells in the second subset of scan cells.

In such an arrangement, the first reset multiplexer is more particularly configured to select between a first functional mode reset signal and a first scan mode reset signal for application to the reset inputs of the respective scan cells of the first subset of scan cells responsive to a first select signal, and the second reset multiplexer is configured to select between a second functional mode reset signal and a second scan mode reset signal for application to the reset inputs of the respective scan cells of the second subset of scan cells responsive to a second select signal. The first and second scan mode reset signals may comprise a single common boundary scan reset signal.

The embodiment to be described in conjunction with FIGS. 2 through 4 further includes a third one of the reset multiplexers 108, with the third reset multiplexer being configured to select a particular one of a plurality of third reset signals for application to reset inputs of respective internal flip-flops of the circuit core. More particularly, the third reset multiplexer is configured to select between a third functional mode reset signal and a third scan mode reset signal for application to the reset inputs of the respective internal flip-flops of the circuit core responsive to a third select signal.

It is to be appreciated, however, that the particular reset multiplexing arrangements described above are presented by way of illustrative example only, and should not be construed as limiting in any way. Numerous alternative arrangements of reset multiplexers or more generally control circuitry may be used to implement the disclosed functionality in which scan test coverage is provided in a particularly efficient manner for one or more of the circuit cores 105 of the integrated circuit 104.

The tester 102 is coupled to the integrated circuit 104 and stores scan data 110 associated with scan testing of the integrated circuit. Such scan data may correspond to test patterns provided by a test pattern generator 112. In other embodiments, at least a portion of the tester 102, such as the test pattern generator 112, may be incorporated into the integrated circuit 104. Alternatively, the entire tester 102 may be incorporated into the integrated circuit 104, as in a built-in self-test (BIST) arrangement.

The test pattern generator 112 may be implemented as an automatic test pattern generator (ATPG), and may be viewed as an example of what is more generally referred to herein as a test generation tool. Such a test generation tool may be part of automated test equipment (ATE) comprising the tester 102.

The particular configuration of testing system 100 as shown in FIG. 1 is exemplary only, and the testing system 100 in other embodiments may include other elements in addition to or in place of those specifically shown, including one or more elements of a type commonly found in a conventional implementation of such a system. For example, various elements of the tester 102 or other parts of the system 100 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

The integrated circuit 104 may be configured for installation on a circuit board or other mounting structure in a computer, server, mobile telephone or other type of communication device. Such communication devices may also be viewed as examples of what are more generally referred to herein as “processing devices.” The latter term is also intended to encompass storage devices, as well as other types of devices comprising data processing circuitry.

Embodiments of the present invention may be configured to utilize compressed or noncompressed scan testing, and are not limited in this regard. However, the embodiment to be described in conjunction with FIGS. 2 through 4 will be described primarily in the context of noncompressed scan testing. In an embodiment with compressed scan testing, the scan test circuitry of the integrated circuit 104 will also comprise a decompressor and a compressor, as will be appreciated by those skilled in the art.

Referring now to FIG. 2, an exemplary circuit core 200 of integrated circuit 104 is shown prior to configuration of a scan chain and associated control circuitry for that circuit core. The circuit core 200 may therefore be viewed as corresponding to a particular one of the circuit cores 105 prior to provision of its one or more associated scan chains 106 and its one or more associated reset multiplexers 108.

The circuit core 200 comprises a plurality of sets 202 of boundary flip-flops 203, including first, second, third and fourth sets of boundary flip-flops 202-1A, 202-1B, 202-2A and 202-2B arranged on respective peripheral sides of the circuit core 200. Each of the sets 202 comprises a plurality of boundary flip-flops 203. Reset inputs of the boundary flip-flops 203 in the first and second sets 202-1A and 202-1B are driven by a first reset signal denoted reset1, and reset inputs of the boundary flip-flops 203 in the third and fourth sets 202-2A and 202-2B are driven by a second reset signal denoted reset2. Each of the boundary flip-flops 203 is associated with either a primary input or a primary output of the circuit core 200.

The circuit core 200 further comprises internal logic circuitry including internal flip-flops 210, large combinational logic blocks 212 and small combinational logic blocks 214. Reset inputs of the internal flip-flops 110 are driven by a third reset signal denoted reset3. The reset signal reset3 is distributed via a reset tree as indicated. The internal flip-flops have respective data inputs D and respective data outputs Q, as do the boundary flip-flops 203. These flip-flops will also have other inputs such as clock inputs that are not expressly shown in the figure. The combinational logic blocks 212 and 214 are also referred to as “logic cones” and each such block drives one or more data inputs of one or more flip-flops 203 or 210 and is driven by one or more data outputs of one or more flip-flops 203 or 210. The flip-flops 203 and 210 are also referred to herein as simply “flops.”

The circuit core 200 as illustrated in FIG. 2 is not yet configured for scan testing of its internal logic circuitry. Accordingly, boundary scan cells 203 are assumed to be conventional boundary flip-flops without scan capability. As indicated previously, it may be necessary under conventional practice to remove scan test circuitry entirely from a given circuit core in order to meet circuit area and performance requirements, leading to an undesirable reduction in fault coverage for the overall design.

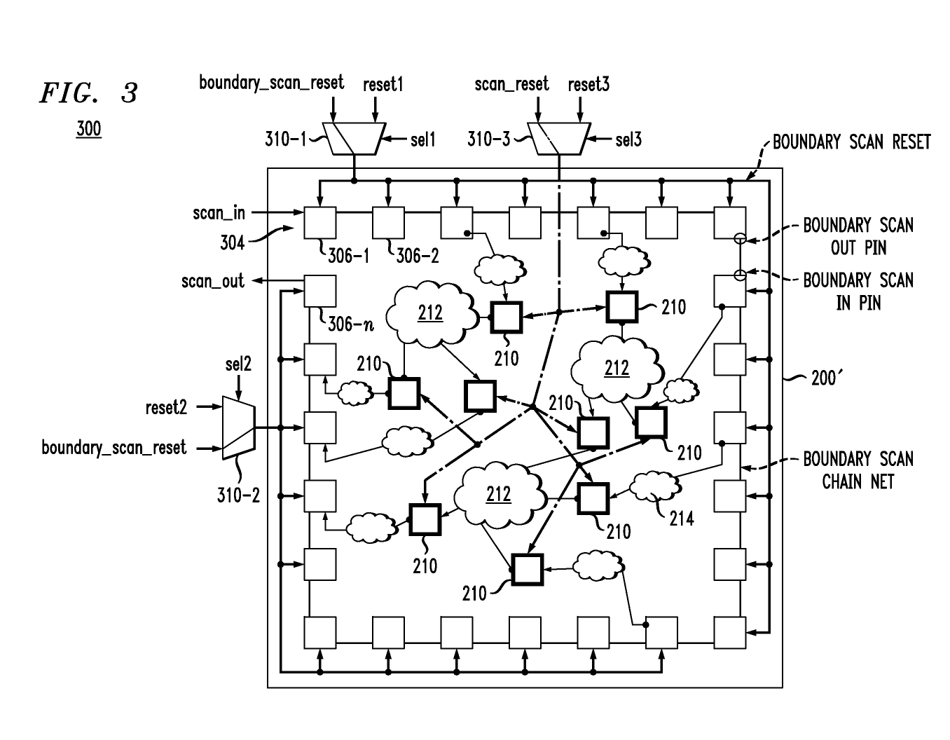

The present embodiment addresses these and other issues by utilizing the boundary flip-flops to form at least one scan chain configured for use in scan testing of the internal logic circuitry comprising internal flip-flops 210 and combinational logic blocks 212 and 214. This configuration is illustrated in FIG. 3, in which a portion 300 of integrated circuit 104 comprises circuit core 200′ that corresponds to circuit core 200 substantially as previously described in conjunction with FIG. 2 but with the boundary flip-flops 203 now configured to form a scan chain 304 comprising respective scan cells 306-1, 306-2, . . . 306-n.

Accordingly, the boundary flip-flops in this embodiment are implemented as respective scan cells that form a single scan chain 304 of length n. The input of the scan chain 304 is denoted scan_in and corresponds to a scan input of the first scan cell 306-1 of the scan chain 304, and the output of the scan chain 304 is denoted scan_out and corresponds to a scan output of the final scan cell 306-n of the scan chain 304. In other embodiments, more than one scan chain may be formed using scan cells corresponding to respective boundary flip-flops arranged around the periphery of the circuit core 200′.

The scan chain 304 is utilized in conjunction with associated control circuitry comprising reset multiplexers 310 to support scan testing of the internal logic circuitry of the circuit core 200′ of FIG. 3. This functionality is achieved without significantly increasing the circuit area overhead or introducing performance penalties, as the boundary flip-flops which would normally be present around the periphery of the circuit core are now also used to implement a scan chain for scan testing.

The combinational logic blocks 212 and 214 in the circuit core as illustrated in FIG. 3 are examples of what are more generally referred to herein as “additional circuitry” that is subject to testing utilizing scan test circuitry in embodiments of the invention. Such blocks may comprise a wide variety of different types of functional logic circuitry, in any combination, and the term “additional circuitry” is intended to be broadly construed so as to cover any such arrangements of logic circuitry.

A scan shift control signal is utilized to cause the scan cells 306 of the scan chain 304 to form a serial shift register during scan testing, although this scan shift control signal is not explicitly shown in FIG. 3. The scan shift control signal may comprise, for example, a scan enable (SE) signal, such that the scan cells of the given scan chain form the serial shift register responsive to the SE signal being at a first designated logic level (e.g., a logic “1” level) and the scan cells capture functional data when the SE signal is at a second designated logic level (e.g., a logic “0” level). A single SE signal may be used to control all of the scan cells 306 of the scan chain 304.

The SE signal in the present embodiment controls configuration of the scan cells 306 of the scan chain 304 to form a serial shift register for shifting in and shifting out of scan test data associated with one or more test patterns applied by the tester 102. The SE signal may therefore be considered a type of scan shift enable signal, or more generally, a type of scan shift control signal.

For simplicity and clarity of illustration, only the scan inputs, scan outputs and reset inputs of the scan cells 306 are shown in FIG. 3, but it is to be appreciated that these scan cells will typically also include other inputs or outputs, such as clock inputs, SE inputs and data outputs.

When the scan chain 304 is configured to form a serial shift register for shifting in and shifting out of scan test data associated with one or more applied test patterns, the scan test circuitry may be said to be in a scan shift phase of a scan test mode of operation. It should be appreciated, however, that a wide variety of other types of scan shift control signals and sets of integrated circuit operating modes and phases may be used in other embodiments. The embodiments described herein therefore do not require the use of any particular definition of operating modes and phases.

The scan chain 304 may be associated with multiple distinct clock domains, or a single clock domain. Accordingly, the scan chain 304 may be implemented as a multiple clock domain scan chain, that is, a scan chain comprising sub-chains associated with respective distinct clock domains. Such sub-chains of a multiple clock domain scan chain may be separated from one another by lockup latches.

Also, one or more of the sub-chains may be selectively bypassed using clock domain bypass circuitry so as to not be part of the serial shift register formed by the scan chain in the scan shift phase. For example, such clock domain bypass circuitry may be configured to bypass one or more of the sub-chains that are determined to be inactive for a particular test pattern, and the clock domain bypass circuitry may bypass different ones of the sub-chains for different test patterns. Additional details regarding clock domain bypass circuitry that may be utilized in embodiments of the invention may be found in U.S. patent application Ser. No. 13/280,797, filed Oct. 25, 2011 and entitled “Dynamic Clock Domain Bypass for Scan Chains,” which is commonly assigned herewith and incorporated by reference herein.

The scan chain 304 is assumed to be one of the scan chains 106 that collectively form at least a portion of the scan test circuitry of the integrated circuit 104. In an embodiment using compressed scan testing, such multiple scan chains 106 are generally arranged in parallel with one another between respective outputs of a decompressor and respective inputs of a compressor, such that in the scan shift phase of the scan test mode of operation, scan test input data from the decompressor is shifted into the scan chains and scan test output data is shifted out of the scan chains into the compressor. The multiple scan chains 106 may all be of the same length, or may have different lengths.

The decompressor of the scan test circuitry in a compressed scan testing embodiment receives compressed scan data from the tester 102 and decompresses that scan data to generate scan test input data that is shifted into the scan chains 106 when such chains are configured as respective serial shift registers in the scan shift phase of the scan test mode of operation. The compressor of the scan test circuitry receives scan test output data shifted out of the scan chains 106, also when such chains are configured as respective serial shift registers in the scan shift phase of the scan test mode of operation, and compresses that scan test output data for delivery back to the tester 102.

Compressed scan input data is applied by tester 102 to M scan inputs of the decompressor, and compressed scan output data is provided from the compressor back to tester 102 via M scan outputs. Assume that N scan chains 106 including scan chain 304 are arranged in parallel between respective outputs of the decompressor and respective inputs of the compressor. Each of the individual scan chains is configurable to operate as a serial shift register in the scan shift phase of a scan test mode of operation of the integrated circuit 104 and also to capture functional data from combinational logic elements. The capture of functional data may be said to occur in a capture phase of the scan test mode. Again, other arrangements of operating modes and phases may be used in other embodiments.

The number N of scan chains is generally much larger than the number M of decompressor inputs or compressor outputs. The ratio of N to M provides a measure of the degree of scan test pattern compression provided in the scan test circuitry. It should be noted, however, that the number of compressor outputs need not be the same as the number of decompressor inputs. For example, there may be M decompressor inputs and P compressor outputs, where M≠P but both M and P are much smaller than N. The scan inputs of the decompressor may be viewed as corresponding to respective ones of what are more generally referred to herein as “scan channels” of the integrated circuit 104.

Additional details regarding the operation of scan compression elements such as the above-noted decompressor and compressor may be found in the above-cited U.S. Pat. No. 7,831,876, entitled “Testing a Circuit with Compressed Scan Subsets.” Again, scan compression elements such as the decompressor and compressor may not be present in other embodiments of the invention. In embodiments of the invention without scan compression, where the decompressor and compressor are eliminated, the scan channels may simply correspond to respective ones of the scan chains 106. The scan chain 304 in the FIG. 3 embodiment may therefore comprise one of a plurality of scan channels of the integrated circuit 104.

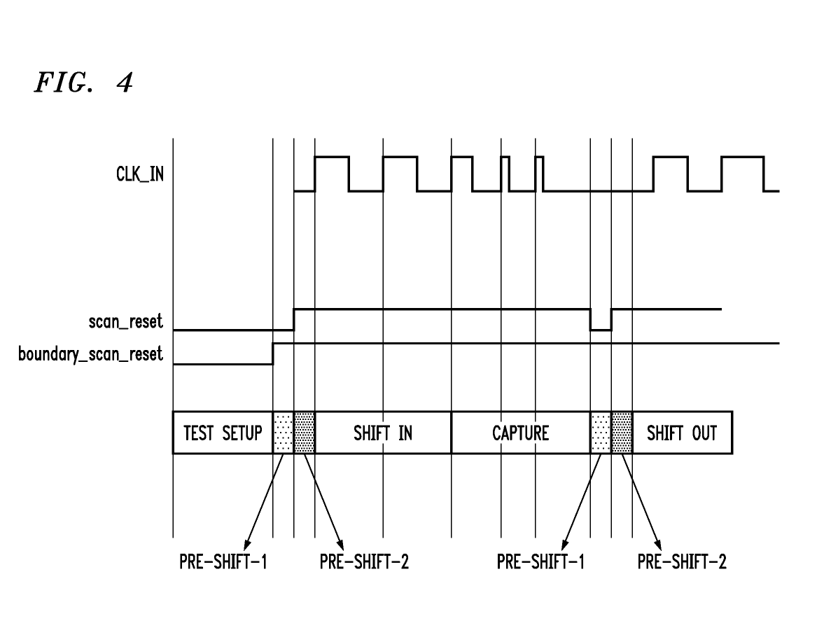

A given test pattern applied to the scan chains 106 in the present embodiment may be viewed as a scan vector, where a scan vector comprises a shift-in phase in which scan test input data is shifted into all of the scan chains, followed by a capture phase in which functional data is captured, followed by a shift-out phase in which scan test output data is shifted out from all of the scan chains. Examples of such shift-in, capture and shift-out phases are shown in the timing diagram to be described in conjunction with FIG. 4. The scan vectors for different test patterns may overlap with one another, in that as input data is shifted in for a given test pattern, captured data for a previous pattern may be shifted out. The shift-in and shift-out phases may be individually or collectively referred to herein as one or more scan shift phases of the scan vector or associated test pattern. As noted above, such scan shift phases may be viewed as being part of a scan test mode of operation of the integrated circuit 104.

Referring now more particularly to the control circuitry arranged outside of the circuit core 200′ in the FIG. 3 embodiment, this control circuitry illustratively comprises reset multiplexing circuitry including a plurality of reset multiplexers 310. The reset multiplexers 310 in the present embodiment comprise respective first, second and third two-to-one multiplexers 310-1, 310-2 and 310-3, although other multiplexing arrangements may be used in other embodiments. These reset multiplexers represent a subset of the reset multiplexers 108 of the control circuitry 107 of integrated circuit 104. Thus, the portion 300 of integrated circuit 104 as illustrated in FIG. 3 represents a given one of the circuit cores 105 plus its associated reset multiplexers 108.

The scan cells 306 of the scan chain 304 in the present embodiment are separated into first and second subsets, with the first subset being controlled by a reset signal selected by the first reset multiplexer 310-1 and the second subset being controlled by a reset signal selected by the second reset multiplexer 310-2.

The first subset of scan cells 306 generally corresponds to the top side and right side peripheral boundary flip-flops of sets 202-1A and 202-1B in FIG. 2, and the second subset of scan cells 306 generally corresponds to the bottom side and left side peripheral boundary flip-flops of sets 202-2A and 202-2B in FIG. 2. As described in conjunction with FIG. 2, the boundary flip-flops of sets 202-1A and 202-1B are normally controlled by the reset signal reset1, and the boundary flip-flops of sets 202-2A and 202-2B are normally controlled by the reset signal reset2. These reset signals reset1 and reset2 are examples of what are more generally referred to herein as “functional mode reset signals,” and are intended to encompass reset signals normally applied to the boundary flip-flops in a functional mode of operation. Accordingly, the reset signals reset1 and reset2 are also referred to herein as respective first and second functional mode reset signals. The circuit core 200′ also utilizes a third functional mode reset signal denoted reset3.

In the present embodiment, the first reset multiplexer 310-1 is configured to select a particular one of a plurality of first reset signals for application to reset inputs of respective scan cells 306 in the first subset of scan cells, the second reset multiplexer 310-2 is configured to select a particular one of a plurality of second reset signals for application to reset inputs of respective scan cells 306 in the second subset of scan cells, and the third reset multiplexer 310-3 is configured to select a particular one of a plurality of third reset signals for application to reset inputs of respective internal flip-flops 210 of the circuit core 200′.

More particularly, in the present embodiment, the first reset multiplexer 310-1 is configured to select between the first functional mode reset signal denoted reset1 and a first scan mode reset signal denoted boundary_scan_reset for application to the reset inputs of the respective scan cells 306 of the first subset of scan cells. This selection is made responsive to a first select signal denoted sel1.

Similarly, the second reset multiplexer 310-2 is configured to select between the second functional mode reset signal denoted reset2 and a second scan mode reset signal also denoted boundary_scan_reset for application to the reset inputs of the respective scan cells 306 of the second subset of scan cells. This selection is made responsive to a second select signal denoted sel2.

The third reset multiplexer 310-3 is configured to select between the third functional mode reset signal denoted reset3 and a third scan mode reset signal denoted scan_reset for application to the reset inputs of the respective internal flip-flops 210 of the circuit core 200′ responsive to a third select signal denoted sel3.

The reset signals reset1, reset2, reset3, boundary_scan_reset and scan_reset and the select signals sel1, sel2 and sel3 can be generated at least in part within control circuitry 107 or elsewhere in the integrated circuit 104. It is also possible that one or more such signals may be provided to the integrated circuit 104 from the tester 102 in conjunction with scan testing of the integrated circuit 104 or portions thereof.

The FIG. 4 timing diagram shows the relationship of exemplary transitions in the boundary_scan_reset and scan_reset signals relative to particular phases of a scan test mode of operation, including a test setup phase, pre-shift phases denoted pre-shift-1 and pre-shift-2, a shift-in phase, a capture phase and a shift-out phase.

In the present embodiment, the first and second scan mode reset signals are the same signal, namely the single common boundary scan reset signal denoted boundary_scan_reset. Thus, this same reset signal is selectable for use with all of the scan cells 306 of the scan chain 304. However, this and other aspects of the above-described reset signaling arrangements are exemplary only, and numerous other reset signaling arrangements can be used in other embodiments.

As indicated above, the scan cells 306 of the scan chain 304 are boundary flip-flops of the circuit core 200′. Accordingly, the FIG. 3 embodiment replaces the boundary flip-flops 203 of FIG. 2 with scan cells 306 but otherwise incorporates no additional scan test circuitry within the circuit core 200′. The area overhead and performance impacts of adapting the circuit core to support scan testing of the internal logic circuitry of the circuit core are therefore minimal. The reset multiplexers 310 are illustratively shown in FIG. 3 as being arranged external to the circuit core 200′ but in other embodiments one or more of these multiplexers may be incorporated into the circuit core itself.

The original circuit core 200 of FIG. 2 may be viewed as a target design that is modified in the manner illustrated in FIG. 3 in order to support scan testing of the internal logic circuitry elements 210, 212 and 214. This modification requires no changes to the internal logic circuitry itself, but only replacement of non-scan boundary flip-flops with respective scan cells configurable to form one or more scan chains, in conjunction with addition of the reset multiplexers 310.

The boundary flip-flops 203 replaced with or otherwise reconfigured as respective scan cells 306 may be identified as the first sequential elements on respective paths from primary inputs of the circuit core and the last sequential elements on respective paths to primary outputs of the circuit core. All other flip-flops within the circuit core are considered to be part of those identified as the internal flip-flops 210. As previously indicated, the boundary flip-flops 203 are replaced with or otherwise reconfigured as respective scan cells 306.

In the scan test mode of operation, the boundary_scan_reset signal drives the reset inputs of all of the scan cells 306 of the scan chain 304 via first and second reset multiplexers 310-1 and 310-2, and the scan_reset signal drives the reset inputs of all of the internal flip-flops 210 via the third reset multiplexer 310-3. This is achieved in the present embodiment by setting the select signals sel1, sel2 and sel3 to logic “1” values.

The timing diagram of FIG. 4 shows the boundary_scan_reset signal and the scan_reset signal in an exemplary scan test mode of operation, as well as an associated clock signal denoted CLK_IN. As indicated previously, the scan test mode of operation in this example includes a test setup phase, a first set of pre-shift phases denoted pre-shift-1 and pre-shift-2, a shift-in phase, a capture phase, a second set of pre-shift phases also denoted pre-shift-1 and pre-shift-2, and a shift-out phase. Both the boundary_scan_reset signal and the scan_reset signal are active low signals in this example, and are initially asserted in conjunction with the test setup phase in order to reset all scan cells 306 and internal flip-flops 210. The boundary_scan_reset signal and the scan_reset signal are then deasserted at the start of the respective pre-shift-1 and pre-shift-2 phases as indicated in the figure. The boundary_scan_reset signal remains deasserted through the first pre-shift-2 phase, the shift-in phase, the capture phase, the second set of pre-shift phases and the shift-out phase, as indicated. However, the scan_reset signal is once again asserted in the second pre-shift-1 phase.

In the functional mode of operation, the reset 1 signal drives the reset inputs of the first subset of scan cells 306 via the first reset multiplexers 310-1, the reset2 signal drives the reset inputs of the second subset of scan cells 306 via the second reset multiplexer 310-2, and the reset3 signal drives the reset inputs of all of the internal flip-flops 210 via the third reset multiplexer 310-3. This is achieved in the present embodiment by setting the select signals sel1, sel2 and sel3 to logic “0” values.

As mentioned above, other reset signaling arrangements may be used in other embodiments. For example, more than three different functional mode reset signals may be used. Also, the particular scan test mode phases, select signal logic states and corresponding multiplexing states may be varied in other embodiments.

The embodiment described in conjunction with FIGS. 2 through 4 allows an otherwise non-scannable circuit core to be adapted for scan testing of its internal logic circuitry in a particularly efficient manner, without requiring the addition of substantial amounts of scan test circuitry and therefore without any significant circuit area or performance penalties. The scan chain 304 is part of the chip-level scan test circuitry controlled by the tester 102 utilizing the scan data 110 and test pattern generator 112.

It is to be appreciated that the particular circuitry arrangements shown in FIGS. 1-3 are presented by way of illustrative example only, and numerous alternative arrangements of scan test circuitry, scan chains, scan cells, control circuitry and reset multiplexers may be used to implement the described functionality. This functionality can be implemented in one or more of the embodiments without any significant negative impact on integrated circuit area requirements or functional timing requirements.

The presence of control circuitry elements of the type described above within integrated circuit 104 may be made apparent to a test pattern generator or other test generation tool so that the tool can take the associated functionality into account in generating test patterns. In order to accomplish this, one or more input files describing the operation of this circuitry may be provided to the test generation tool.

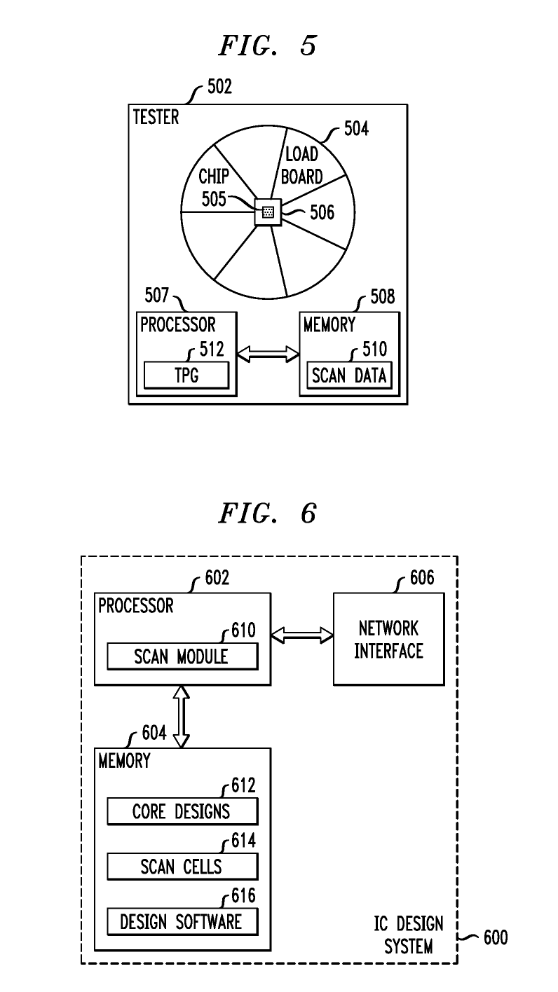

The tester 102 in the testing system 100 of FIG. 1 need not take any particular form, and various conventional testing system arrangements can be modified in a straightforward manner to support the scan testing functionality disclosed herein. One possible example is shown in FIG. 5, in which a tester 502 comprises a load board 504 in which an integrated circuit 505 to be subject to scan testing using the techniques disclosed herein is installed in a central portion 506 of the load board 504. The tester 502 also comprises processor and memory elements 507 and 508 for executing stored program code. In the present embodiment, processor 507 is shown as implementing a test pattern generator 512, which may be implemented as an ATPG. Associated scan data 510 is stored in memory 508. Numerous alternative testers may be used to perform scan testing of an integrated circuit as disclosed herein. Also, as indicated previously, in alternative embodiments at least portions of the tester 502 may be incorporated into the integrated circuit itself, as in BIST arrangement.

The insertion of scan chains 106 and associated control circuitry 107 of a given integrated circuit design may be performed in a processing system 600 of the type shown in FIG. 6. Such a processing system in this embodiment more particularly comprises a design system configured for use in designing integrated circuits such as integrated circuit 104 to include scan chains 106 and associated control circuitry 107.

The system 600 comprises a processor 602 coupled to a memory 604. Also coupled to the processor 602 is a network interface 606 for permitting the processing system to communicate with other systems and devices over one or more networks. The network interface 606 may therefore comprise one or more transceivers. The processor 602 implements a scan module 610 for supplementing core designs 612 with scan cells 614 and associated control circuitry elements in the manner disclosed herein, in conjunction with utilization of integrated circuit design software 616.

By way of example, the scan chains 106 and associated control circuitry 107 may be generated in system 600 using an RTL description and then synthesized to gate level using a specified technology library. More particularly, the scan cells 306 and reset multiplexers 310 for a given circuit core can be inserted into an integrated circuit design following normal scan insertion, possibly using a design compiler and automated script.

A test generation model may then be created for generating test patterns using a test generation tool. Control files or other types of input files may be used to provide the test generation tool with information such as the particular scan chains that are associated with particular circuit cores and reset multiplexers in a given embodiment. Once the corresponding rules are in place, a rule checker may be run so that the test generation tool has visibility of the scan chains taking into account the operation of the associated reset multiplexers. Test patterns may then be generated for the scan chain circuitry.

Elements such as 610, 612, 614 and 616 are implemented at least in part in the form of software stored in memory 604 and processed by processor 602. For example, the memory 604 may store program code that is executed by the processor 602 to implement particular scan testing functionality of module 610 within an overall integrated circuit design process. The memory 604 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 602 may comprise a microprocessor, CPU, ASIC, FPGA or other type of processing device, as well as portions or combinations of such devices. The memory 508 of FIG. 5 may be viewed as another illustrative example of a computer program product as the latter term is used herein.

As indicated above, embodiments of the invention may be implemented in the form of integrated circuits. In a given such integrated circuit implementation, identical die are typically formed in a repeated pattern on a surface of a semiconductor wafer. Each die includes scan test circuitry having scan chains and associated control circuitry as disclosed herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

It should again be emphasized that the embodiments of the invention as described herein are intended to be illustrative only. For example, other embodiments of the invention can be implemented using a wide variety of other types of integrated circuits, scan test circuitry and additional circuitry subject to testing, with different types and arrangements of scan cells, scan chains and associated control circuitry, as well as different types and arrangements of reset multiplexers, scan test mode phases and control signaling, than those included in the embodiments described herein. These and numerous other alternative embodiments within the scope of the following claims will be readily apparent to those skilled in the art.

What is claimed is:

1. An integrated circuit comprising:
scan test circuitry comprising at least one scan chain having a plurality of scan cells; and
additional circuitry subject to testing utilizing the scan test circuitry;
the scan test circuitry further comprising:
control circuitry configured to control selective application of at least a particular one of a plurality of reset signals to reset inputs of at least a subset of the scan cells of the scan chain.

2. The integrated circuit of claim 1 wherein the scan cells of the scan chain comprise respective boundary flip-flops of a circuit core of the integrated circuit.

3. The integrated circuit of claim 1 wherein the control circuitry comprises reset multiplexing circuitry configured to select between a functional mode reset signal and a scan mode reset signal for application to the reset inputs of at least a subset of the scan cells of the scan chain responsive to a select signal.

4. The integrated circuit of claim 1 wherein the scan cells are separated into at least first and second subsets and said control circuitry comprises:
a first reset multiplexer configured to select a particular one of a plurality of first reset signals for application to reset inputs of respective scan cells in the first subset of scan cells; and
a second reset multiplexer configured to select a particular one of a plurality of second reset signals for application to reset inputs of respective scan cells in the second subset of scan cells.

5. The integrated circuit of claim 4 wherein at least one of the first and second reset multiplexers comprises a two-to-one multiplexer.

6. The integrated circuit of claim 4 wherein the first reset multiplexer is configured to select between a first functional mode reset signal and a first scan mode reset signal for application to the reset inputs of the respective scan cells of the first subset of scan cells responsive to a first select signal.

7. The integrated circuit of claim 6 wherein the second reset multiplexer is configured to select between a second functional mode reset signal and a second scan mode reset signal for application to the reset inputs of the respective scan cells of the second subset of scan cells responsive to a second select signal.

8. The integrated circuit of claim 7 wherein the first and second scan mode reset signals comprise a single common boundary scan reset signal.

9. The integrated circuit of claim 4 wherein the control circuitry further comprises a third reset multiplexer configured to select a particular one of a plurality of third reset signals for application to reset inputs of respective internal flip-flops of the additional circuitry.

10. The integrated circuit of claim 9 wherein the third reset multiplexer is configured to select between a third functional mode reset signal and a third scan mode reset signal for application to the reset inputs of the respective internal flip-flops of the additional circuitry responsive to a third select signal.

11. The integrated circuit of claim 1 wherein the control circuitry comprises:
a first reset multiplexer configured to select a particular one of a first plurality of reset signals for application to reset inputs of at least a subset of the scan cells of the scan chain; and
at least one additional reset multiplexer configured to select a particular one of an additional plurality of reset signals for application to reset inputs of respective internal flip-flops of the additional circuitry.

12. The integrated circuit of claim 1 wherein the control circuitry comprises:
a first reset multiplexer configured to select one of a first functional mode reset signal and a first scan mode reset signal for application to reset inputs of respective scan cells of the scan chain; and
at least one additional reset multiplexer configured to select one of an additional functional mode reset signal and an additional scan mode reset signal for application to reset inputs of respective internal flip-flops of the additional circuitry.

13. A processing device comprising the integrated circuit of claim 1.

14. A method comprising:
configuring scan test circuitry to include at least one scan chain having a plurality of scan cells; and
controlling selective application of at least a particular one of a plurality of reset signals to reset inputs of at least a subset of the scan cells of the scan chain.

15. The method of claim 14 wherein controlling selective application of at least a particular one of a plurality of reset signals comprises selecting between a functional mode reset signal and a scan mode reset signal for application to the reset inputs of at least a subset of the scan cells of the scan chain responsive to a select signal.

16. The method of claim 14 wherein the scan cells are separated into at least first and second subsets and controlling selective application of at least a particular one of a plurality of reset signals comprises:
selecting a particular one of a plurality of first reset signals for application to reset inputs of respective scan cells in the first subset of scan cells; and
selecting a particular one of a plurality of second reset signals for application to reset inputs of respective scan cells in the second subset of scan cells.

17. The method of claim 16 wherein controlling selective application of at least a particular one of a plurality of reset signals further comprises selecting a particular one of a plurality of third reset signals for application to reset inputs of respective internal flip-flops of the additional circuitry.

18. The method of claim 14 wherein controlling selective application of at least a particular one of a plurality of reset signals comprises:
selecting a particular one of a first plurality of reset signals for application to reset inputs of at least a subset of the scan cells of the scan chain; and
selecting a particular one of an additional plurality of reset signals for application to reset inputs of respective internal flip-flops of the additional circuitry.

19. The method of claim 14 wherein controlling selective application of at least a particular one of a plurality of reset signals comprises:
selecting between a first functional mode reset signal and a first scan mode reset signal for application to reset inputs of respective scan cells of the scan chain; and
selecting between an additional functional mode reset signal and an additional scan mode reset signal for application to reset inputs of respective internal flip-flops of the additional circuitry.

20. A computer-readable storage medium having computer program code embodied therein, wherein the computer program code when executed in a testing system causes the testing system to perform the method of claim 14.

21. A processing system comprising:
a processor; and
a memory coupled to the processor and configured to store information characterizing an integrated circuit design;
wherein the processing system is configured to provide scan test circuitry within the integrated circuit design, the scan test circuitry comprising at least one scan chain having a plurality of scan cells;
the scan test circuitry further comprising:
control circuitry configured to control selective application of at least a particular one of a plurality of reset signals to reset inputs of at least a subset of the scan cells of the scan chain.
